(19) United States
(12) Patent Application Publication
(10) Pub. No.: US 2012/0242395 A1
(43) Pub. Date: Sep. 27, 2012

(54) LOW LOSS SWITCHED CAPACITOR

(75) Inventor: Yongwang Ding, Milipitas, CA (US)

(73) Assignee: QUALCOMM INCORPORATED, San Diego, CA (US)

(21) Appl. No.: 13/070,280

(22) Filed: Mar. 23, 2011

(51) Int. Cl. H03B 5/12; H03K 17/687; H01L 27/06

(52) U.S. Cl. 327/427; 331/117 FE; 257/296; 257/E27.016

(57) ABSTRACT

An integrated circuit including a capacitor bank is disclosed. The capacitor bank includes one or more cells. Each cell may include two capacitors in series and a transistor in parallel with one of the capacitors. The transistor switches a capacitance of the parallel capacitor in or out of a larger circuit.

### TECHNICAL FIELD

The present disclosure relates generally to electronic devices for communication systems. More specifically, the present disclosure relates to a highly reliable, low loss switched capacitor.

### BACKGROUND

Electronic devices (cellular telephones, wireless modems, computers, digital music players, Global Positioning System units, Personal Digital Assistants, gaming devices, etc.) have become a part of everyday life. Small computing devices are now placed in everything from automobiles to housing locks. The complexity of electronic devices has increased dramatically in the last few years. For example, many electronic devices have one or more processors that help control the device, as well as a number of digital circuits to support the processor and other parts of the device.

Wireless communication systems are widely deployed to provide various types of communication content such as voice, video, data, and so on. These systems may be multiple-access systems capable of supporting simultaneous communication of multiple wireless communication devices with one or more base stations.

For proper reception and transmission of wireless signals on a wireless communication network, a wireless communication device may use one or more radio frequency (RF) communication circuits. Wireless communication device and/or wireless communication system specifications may require that the amplitude of signals generated within wireless communication devices meet certain requirements while also maintaining high levels of reliability. In addition, a wireless communication device may operate using batteries. Therefore, benefits may be realized by providing improvements to RF circuits.

### SUMMARY

An integrated circuit including a capacitor bank is disclosed. The capacitor bank includes one or more cells. Each cell may include two capacitors in series and a transistor in parallel with one of the capacitors. The transistor switches a capacitance of the parallel capacitor in or out of a larger circuit.

Each cell may include one or more resistors that bias the transistor using a control signal. The transistor may be an n-type metal-oxide-semiconductor (NMOS) field effect transistor. Capacitances of the capacitors may be matched in a 1:1 ratio or not. The largest capacitance of a second cell may be double a largest capacitance of a first cell and half a largest capacitance of a third cell. The transistor may switch a capacitance of the parallel capacitor in or out of a larger circuit.

In one configuration, the larger circuit includes a a voltage controlled oscillator (VCO) core. The VCO core may includes an inductor/capacitor (LC) tank that generates a desired frequency using the capacitor bank. The VCO core may also include a first n-type metal-oxide-semiconductor (NMOS) field effect transistor with a source connected to ground, a drain connected to a first VCO core output and a gate connected to a second VCO core output. The VCO core may also include a second NMOS field effect transistor with a source connected to ground, a drain connected to the second VCO core output and a gate connected to the first VCO core output. The VCO core may also include a first p-type metal-oxide-semiconductor (PMOS) field effect transistor with a source connected to a voltage supply, a drain connected to the first VCO core output and a gate connected to the second VCO core output. The VCO core may also include a second PMOS field effect transistor with a source connected to the voltage supply, a drain connected to the second VCO core output and a gate connected to the first VCO core output.

The larger circuit may also include a buffer with a first portion and a second portion. The first portion may include a first capacitance connected to the second VCO core output and a gate of a third p-type metal-oxide-semiconductor (PMOS) field effect transistor. The first portion may also include the third PMOS field effect transistor with a source connected to the voltage supply and a drain connected to the first portion output. The first portion may also include a second capacitance connected to the second VCO core output and a gate of a third n-type metal-oxide-semiconductor (NMOS) field effect transistor. The first portion may also include the third NMOS field effect transistor with a source connected to ground and a drain connected to the first portion output. The second portion may include a third capacitance connected to the first VCO core output and a gate of a fourth p-type metal-oxide-semiconductor (PMOS) field effect transistor. The second portion may also include the fourth PMOS field effect transistor with a source connected to the voltage supply and a drain connected to the second portion output. The second portion may also include a fourth capacitance connected to the first VCO core output and a gate of a fourth n-type metal-oxide-semiconductor (NMOS) field effect transistor. The second portion may also include the fourth NMOS field effect transistor with a source connected to ground and a drain connected to the second portion output. One or more of the first capacitance, second capacitance, third capacitance and fourth capacitance may be generated using the capacitor bank.

An apparatus including a capacitor bank is also disclosed. The bank includes one or more cells. Each cell includes two capacitors in series and a transistor in parallel with one of the capacitors.

An apparatus including a capacitor bank is also disclosed. The bank includes one or more cells. Each cell includes capacitive means in series and a means for switching in parallel with one of the capacitive means.

A method for including or excluding a capacitance from a larger circuit is disclosed. An input signal is divided using two or more capacitors in series with each other. A capacitance is switched in or out of the larger circuit using a transistor that is in parallel with fewer than all of the capacitors.

### BRIEF DESCRIPTION OF THE DRAWINGS

FIG. 1 is a block diagram illustrating a wireless communication system;

FIG. 2 is a circuit diagram illustrating one configuration of a switched capacitor;

FIG. 3 is a circuit diagram illustrating another configuration of a switched capacitor;

FIG. 4 is a circuit diagram illustrating another configuration of a switched capacitor;

FIG. 5 is a circuit diagram of a capacitor bank;

FIG. 6 is a block diagram illustrating a phase locked loop (PLL);

FIG. 7 is a circuit diagram illustrating a voltage controlled oscillator (VCO) core and a VCO buffer;

FIG. 8 is a flow diagram illustrating a method for including or excluding a capacitance from a larger circuit;

FIG. 9 illustrates certain components that may be included within base station; and

FIG. 10 illustrates certain components that may be included within a wireless communication device.

### DETAILED DESCRIPTION

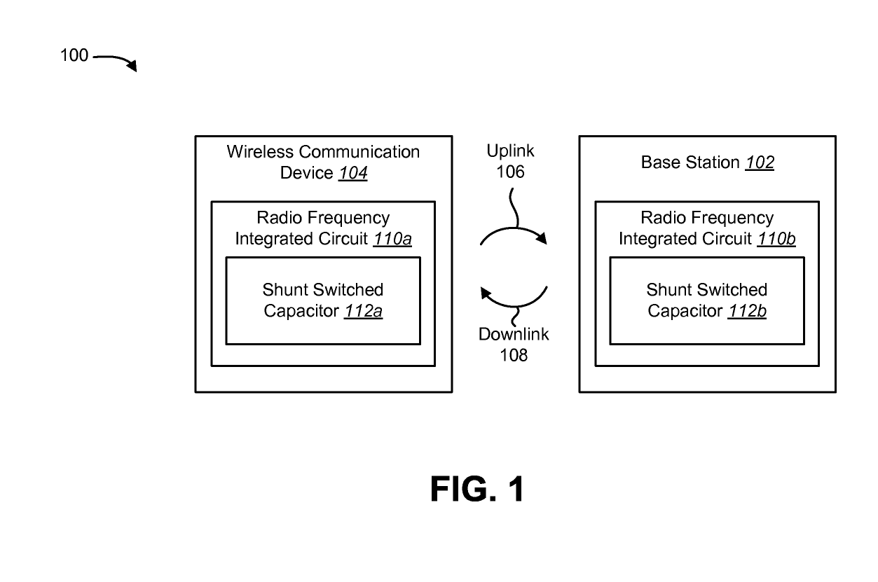

FIG. 1 is a block diagram illustrating a wireless communication system 100. A base station 102 may communicate with one or more wireless communication devices 104. The base station 102 may also be referred to as, and may include some or all of the functionality of, an access point, a broadcast transmitter, a Node B, an evolved Node B, etc. Each base station 102 may provide communication coverage for a particular geographic area.

A wireless communication device 104 may be referred to as, and may include some or all of the functionality of, a terminal, an access terminal, a user equipment (UE), a mobile device, a subscriber unit, a station, etc. The wireless communication device 104 may be a cellular phone, a personal digital assistant (PDA), a wireless device, a wireless modem, a handheld device, a laptop computer, etc. The wireless communication device 104 may communicate with zero, one, or multiple base stations 102 on the downlink (DL) 108 and/or uplink (UL) 106 at any given moment using an antenna. The downlink 108 (or forward link) refers to the communication link from a base station 102 to the wireless communication device 104, and the uplink 106 (or reverse link) refers to the communication link from the wireless communication device 104 to the base station 102.

The wireless communication device 104 and the base station 102 may have one or more radio frequency (RF) integrated circuits 110a-b. For example, the RF integrated circuits 110a-b may be a voltage controlled oscillator (VCO) or a power amplifier. These circuits 110a-b may include one or more shunt switched capacitors 112a-b. Switched capacitors may be used in analog/RF IC designs for tuning the impedance of a circuit, changing a signal phase, transforming the impedance of a circuit, providing signal division within a circuit, etc. The terms “switched capacitor” and “tuning capacitor” may be used interchangeably herein, and refer to a circuit with at least one capacitor and one switch that operates to include or exclude capacitance from a larger circuit. As discussed below, a shunt switched capacitor 112a-b may be a highly reliable switched capacitor and may be subject to low insertion loss.

The wireless communication system 100 may be multiple-access systems capable of supporting communication with multiple users by sharing the available system resources (e.g., bandwidth and transmit power). Examples of such multiple-access systems include code division multiple access (CDMA) systems, time division multiple access (TDMA) systems, frequency division multiple access (FDMA) systems, orthogonal frequency division multiple access (OFDMA) systems, and spatial division multiple access (SDMA) systems.

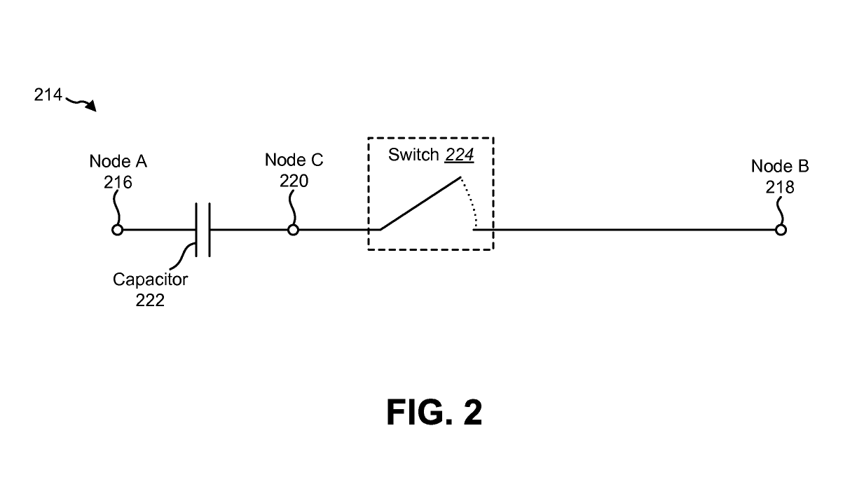

FIG. 2 is a circuit diagram illustrating one configuration of a switched capacitor 214. The switched capacitor 214 may include a capacitor 222 and a switch 224 either in series or in parallel, e.g., the switch 224 may be a transistor. In either case, the switch 224 may experience the voltage stress of the full wave when it is open. In other words, if the voltage swing from node A 216 to node B 218 is 3 V, the voltage swing across the switch 224 (from node C 220 to node B 218) may experience the stress of all 3 V when the switch 224 is open. Since the switch 224 may be an active device with a limited swing tolerance, the voltage stress may cause a reliability issue when the signal swing is large, especially in power amplifiers where maximum signal swings may be desired. Furthermore, this configuration may have a relatively low quality factor because the resistance of the switch 224 in series with the capacitor 222 may determine the quality factor, i.e., Q factor.

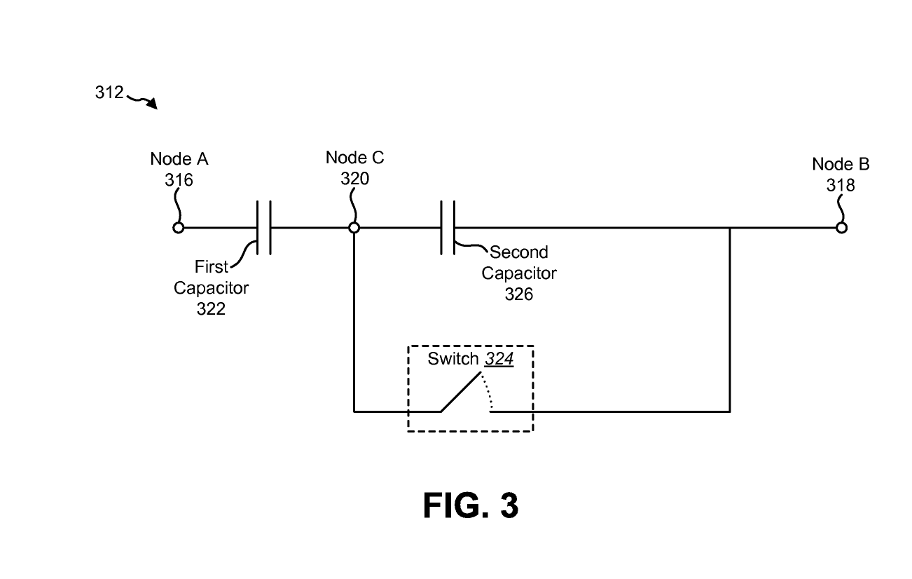

FIG. 3 is a circuit diagram illustrating another configuration of a switched capacitor 312. The switched capacitor 312 may include a first capacitor 322 in series with a second capacitor 326 and one or more switches 324 (e.g., transistors) in parallel with one or more, but not all capacitor(s) 326. In this configuration, the switch 324 may only experience the voltage stress of a divided signal swing in any state. Therefore, the stress condition of the switch 324 may be relaxed by the division ratio. In other words, if the voltage swing from node A 316 to node B 318 is 3 V, the voltage swing across the switch 324 (from node C 320 to node B 318) may experience the voltage stress of only about 1.5 V when the switch 324 is open and the first capacitor 322 is matched with the second capacitor 326. Alternatively, if the first capacitor 322 is not matched with second capacitor 322, the swing across the switch 324 may be given according to Equation (1):

$${V}_{CB} = {V}_{AB} ( \frac{{C}_{1}}{{C}_{1} + {C}_{2}} ) \qquad ( 1 )$$

where V_{CB} is the voltage swing from node C 320 to node B 318, V_{AB} is the voltage swing from node A 316 to node B 318, C₁ is the capacitance of the first capacitor 322 and C₂ is the capacitance of the second capacitor 326. For example, the capacitance of C₁:C₂ may be 1:2, 1:3, 1:4, 1:5, 1:10, 2:1, 3:1, 4:1, 5:1, 10:1, etc. Therefore, to take the same maximum stress on the switch 324 for a given process, the switched capacitor 312 may tolerate higher signal swing. This may lead to higher reliability of the switch 324.

This configuration may also reduce switch 324 loss, i.e., this configuration may have a high quality factor. Specifically, the quality factor (Q factor) may be determined by the first capacitor 322 in series with the resistance of the switch 324 that is in parallel with the second capacitor 326. The quality factor of the switched capacitor 312 in FIG. 3 may be higher than the quality factor of the switched capacitor 214 in FIG. 2, e.g., greater than 50. However, this configuration may also reduce the tuning range of the switched capacitor 312, e.g., 50% of other switched capacitors.

The quality factor (Q) of a series RC network may be given by Equation (2):

$$Q = \frac{1}{ω R C} \qquad ( 2 )$$

where ω is the angular frequency, and R and C are the values of the resistor and the capacitor in series, respectively. For example, the quality factor of the switched capacitor 214 in FIG. 2, when the switch is closed, is given by Equation (3):

$${Q}_{1} = \frac{1}{ω {R}_{on} C} \qquad ( 3 )$$

where Rₒₙ is the on resistance of the switch. Similarly, the quality factor of the switched capacitor 312 in FIG. 3, when the switch is closed, is given by Equation (4):

$${Q}_{2} = \frac{1}{ω {R}_{eff} {C}_{eff}} \qquad ( 4 )$$

where R_{eff} is the effective series resistance, and C_{eff} is the effective series capacitance. R_{eff} is given by Equation (5):

$${R}_{eff} = \frac{{R}_{on}}{1 + {Q}_{C 2}^{2}} \qquad ( 5 )$$

where Q_{C2} is the quality factor of the parallel Rₒₙ (closed switch on resistance) and C2 (the second capacitor), which is given by Equation (6):

Q_{C2}=ωRₒₙC₂ (6)

C_{eff} may be calculated as C1 and the effective series capacitor derived from the parallel Rₒₙ and C2, as given by Equation (7):

$$\begin{matrix}{C}_{eff} = \frac{{C}_{1} + {C}_{2 S}}{{C}_{1} \cdot {C}_{2 S}} where & ( 7 ) \\ {C}_{2 S} = ( 1 + \frac{1}{{Q}_{C 2}^{2}} ) \cdot {C}_{2} & ( 8 )\end{matrix}$$

When C_{eff} is the same as C in Equation (3), the quality factor of the switchable capacitor when the switch is closed is improved by (1+Q²_{C2}) times, as is given by Equation (9):

$${Q}_{2} = \frac{1 + {Q}_{C 2}^{2}}{{Q}_{1}} \qquad ( 9 )$$

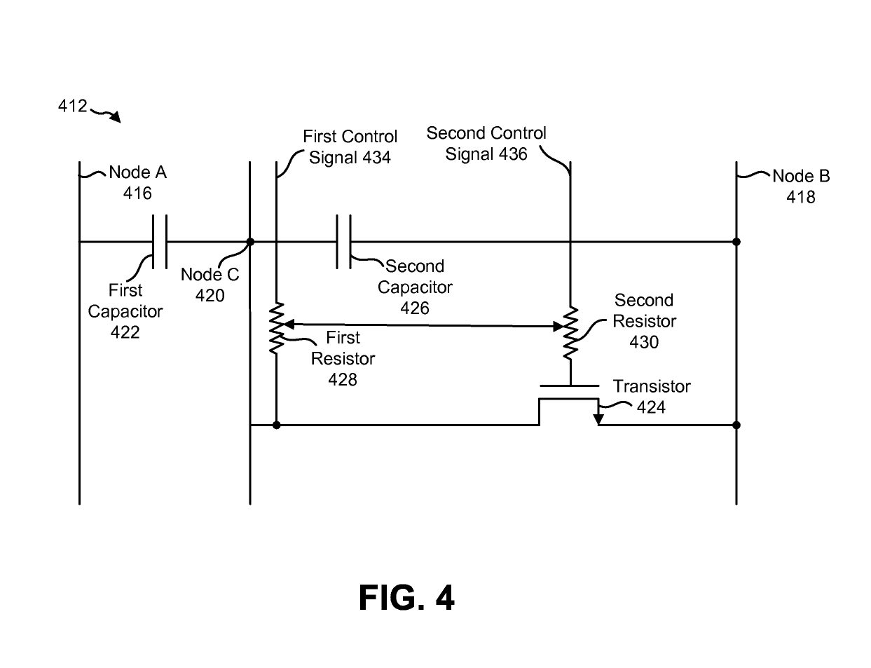

FIG. 4 is a circuit diagram illustrating another configuration of a switched capacitor 412. The switched capacitor 412 may include a first capacitor 422 in series with a second capacitor 426 that is in parallel with a transistor 424. Alternatively, there may be more capacitors that are in series with each other and the transistor 424 may be in parallel with more than one capacitor, but not all of the capacitors, e.g., a transistor 424 in parallel with two series capacitors and then a third capacitor in series with the parallel combination. The transistor 424 may be an n-type metal-oxide-semiconductor (NMOS) field effect transistor and may be biased by a first resistor 428 and a second resistor 430. The first resistor 428 and second resistor 430 may be variable resistors. Like the previous configuration, the transistor 424 may only experience the voltage stress of a divided signal swing in any state according to the division ratio of the capacitors, illustrated in Equation (1). In other words, the voltage swing across the transistor 424 (from node C 420 to node B 418) may be a fraction of the voltage swing from node A 416 to node B 418. Furthermore, a first control signal 434 and a second control signal 436 may affect the characteristics of the switched capacitor 412.

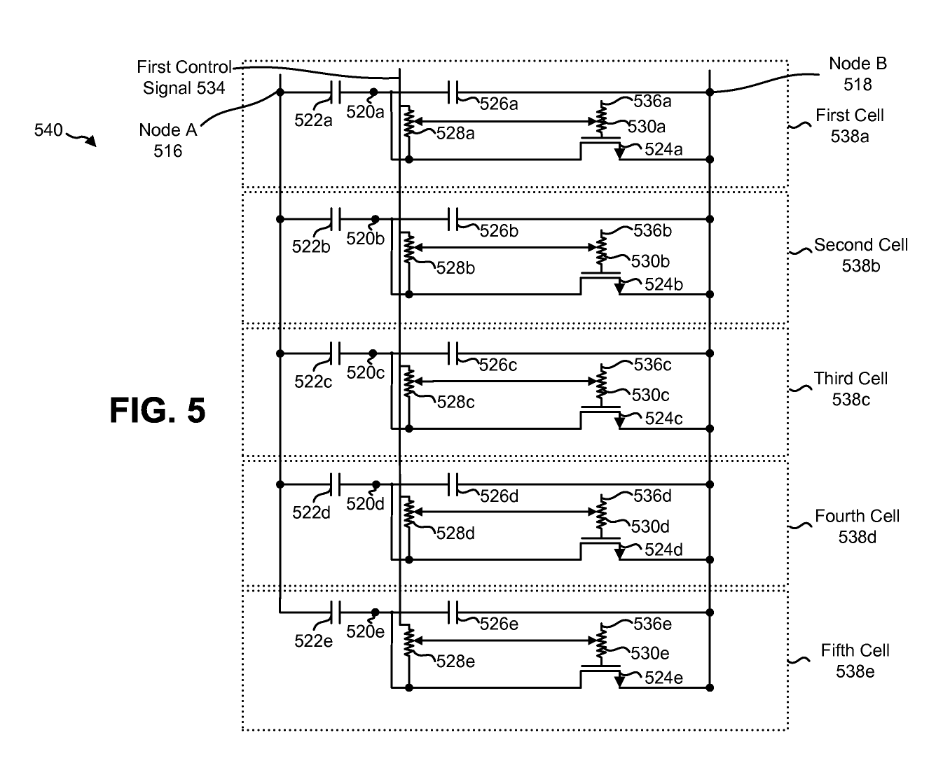

FIG. 5 is a circuit diagram of a capacitor bank 540. In the illustrated configuration, the capacitor bank 540 includes five cells 538a-e, where each cell includes a switched capacitor, e.g. the switched capacitor 412 illustrated in FIG. 4. Therefore, the circuit elements and signals in FIG. 5 may correspond to the circuit elements and signals described in FIG. 4. In other words, the first capacitors 522a-e, second capacitors 526a-e, first resistors 528a-e, second resistors 530a-e, transistors 524a-e, first control signal 534 and second control signals 536a-e in FIG. 5 may operate similar to the first capacitor 422, second capacitor 426, first resistor 428, second resistor 430, transistor 424, first control signal 434 and second control signal 436 in FIG. 4.

The capacitor bank 540 may include or exclude capacitances from one or more cells 538 (i.e., switched capacitors) to create a capacitance from node A 516 to node B 518. Including or excluding cells 538 may include using control signals 536a-e. Without the control signal 534, the node Cs 520a-e may be undefined or floating when the switches 524a-e are turned off, which is undesired. Furthermore, the cells 538 may not be identical. In one configuration, the capacitances of the cells 538 may increase by double, relative to the previous cell, i.e., binary bit incrementing. In other words, if the largest capacitance added from node A 516 to node B 518 by the first cell 538a is X, the largest capacitance added by the second cell 538b may be 2×. Similarly, the largest capacitance added by the third cell 538c may be 4×, the largest capacitance added by the fourth cell 538d may be 8×, and the largest capacitance added by the fifth cell 538e may be 16×. Therefore, there may be 32 possible capacitance values achievable by the capacitance bank 540. Although five cells 538 are illustrated, the capacitor bank 540 may include more or fewer than five cells. In general, the number of possible capacitance values a capacitor bank is able to generate with n cells may be 2ⁿ.

Likewise, the transistors 524 may not be identical. In one configuration, the resistive values of each transistor 524 increases with binary bit increment. In other words, if the resistive value of the transistor 524a in the first cell 538a is ×, the resistive value of the transistor 524b in the second cell 538b may be 2×. Furthermore, the resistive value of the transistor 524c in the third cell 538c may be 4×, the resistive value of the transistor 524d in the fourth cell 538d may be 8× and the resistive value of the transistor 524e in the fifth cell 538e may be 16×. Alternatively, the capacitors and/or the transistors 524 may be identical and the number of possible capacitance values may be equal to the number of cells in the capacitor bank. In theory, there may be no limitation on resistor 530a-e or capacitor 522a-e, 526a-e range. However, in reality the capacitors 522a-e, 526a-e may be limited by the intended tuning range and the parasitic capacitance, i.e., the parasitic capacitance will reduce the overall capacitive tuning range. Furthermore, the resistors 530a-e may be used to provide DC bias only and may be large enough to maintain enough quality factor but small enough to meet an initial power settling metric.

Like before, the voltage swing across the transistors 524a-e (from node C 520a-e to node B 518) may be less than the voltage swing across the entire bank 540 (from node A 516 to node B 518). This may result in lower voltage stress on the transistors 524a-e and lead to relatively high reliability. Furthermore, the Q factor of each cell 538 may be relatively high.

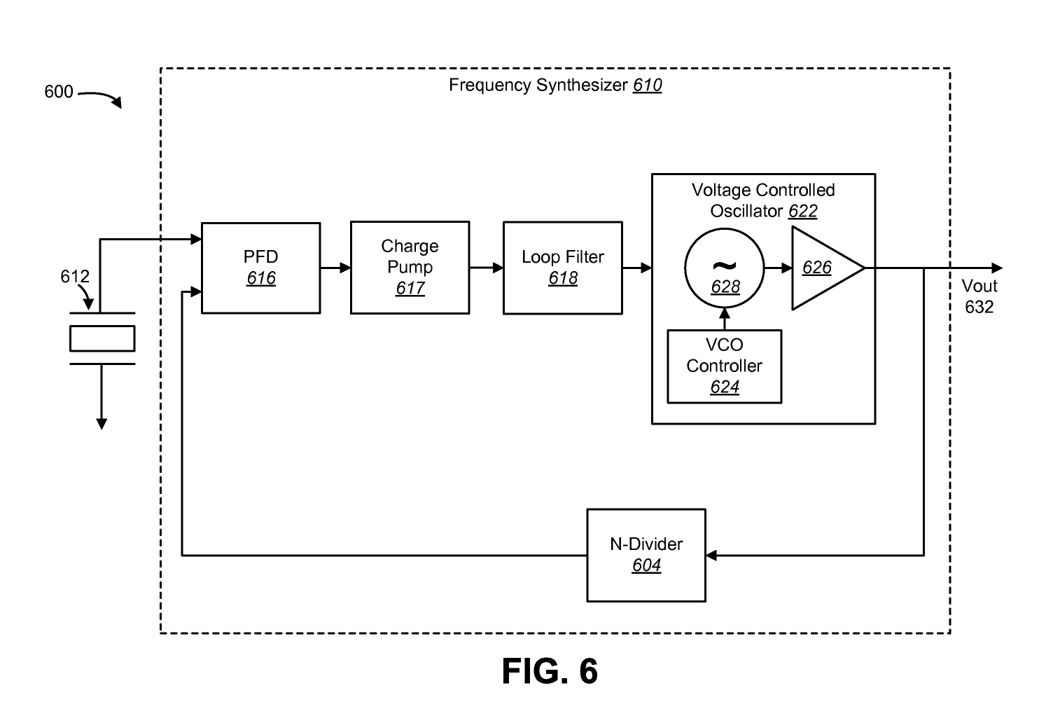

FIG. 6 is a block diagram illustrating a phase locked loop (PLL) 600. The PLL 600 may be implemented on a single integrated circuit and may include various modules in a feedback configuration. Specifically, the PLL 600 may implement a frequency synthesizer 610 that is capable of generating a range of frequencies from a single fixed reference signal 612, e.g., oscillator.

In one configuration, a reference signal 612 with a predetermined frequency may be provided by a crystal oscillator and/or another suitable signal generator, from which the frequency synthesizer 610 may generate an output signal, Vout 632, that is fixed, i.e., locked, in frequency and/or phase to the reference signal 612. The frequency synthesizer 610 may also include a phase frequency detector (PFD) 616, a charge pump 617, a loop filter 618 and one or more VCOs 622 operating in a closed feedback loop. Optionally, the frequency synthesizer may also include an r-divider (not shown) that may alter the reference signal 612 prior to comparison at the PFD 616, e.g., divide the frequency of the reference signal 612.

In one configuration, the PFD 616 may compare the reference signal 612 to the output of the n-divider 604 in the feedback loop. The output of the n-divider 604 may be a signal with a frequency equal to the frequency of the output signal, Vout 632, divided by an integer parameter N. The PFD 616 may determine any differences in phase and/or frequency between the output of the n-divider 604 and the reference signal 612 and express this difference as “pump up” or “pump down” pulses to the charge pump 617. The charge pump 617 may then provide charge to a loop filter 618 that may filter the charge pump 617 output to the tuning port of the VCO 622. For example, the PFD 616 may generate a digital output signal consisting of high and/or low pulses of varying lengths. The charge pump 617 may receive this signal and produce an output corresponding to the pump up and/or pump down signals from the PFD 616. The charge pump 617 output may subsequently be filtered by the loop filter 618 to provide a stable voltage level to the VCO(s) 622.

Upon receiving a signal from the charge pump 617 via the loop filter 618, the VCO 622 may generate an output signal 632 having a frequency based on the voltage level of the input signal provided by the loop filter 618. Signal generation at the VCO 622 may be performed by VCO core 628. The present systems and methods may use switched capacitors 312 to adjust the frequency of the VCO 622. Specifically, a VCO controller 624 may use a switched capacitor bank 540 to move capacitances in or out of an LC circuit to produce oscillation at different frequencies. Additionally, a VCO buffer 626 may amplify the output of the VCO core 628. The VCO output signal 632 may be divided and compared again to the reference signal 612 to facilitate continuous adjustment of Vout 632 in relation to the reference signal 612.

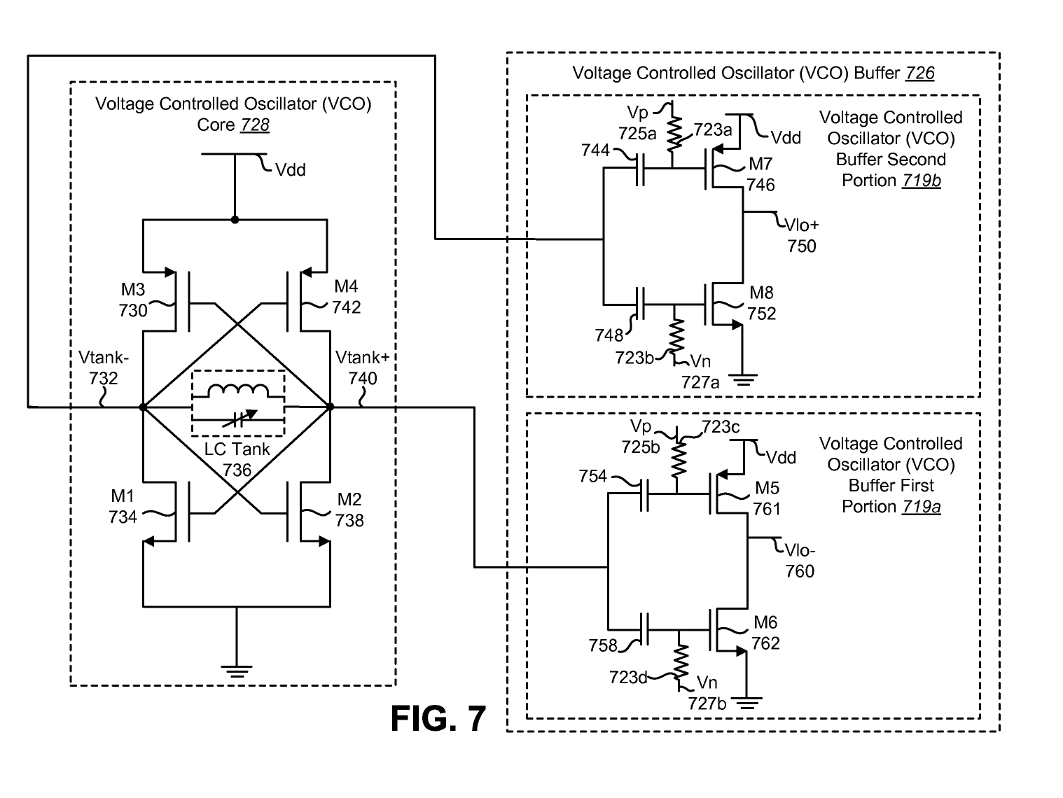

FIG. 7 is a circuit diagram illustrating a VCO core 728 and a VCO buffer 726. The VCO core 728 of FIG. 7 may be one configuration of the VCO core 628 illustrated in FIG. 6. The VCO core 728 may include a first n-type metal-oxide-semiconductor (NMOS) field effect transistor Ml 734 with the source of Ml 734 connected to ground and the drain of Ml 734 connected to an output Vtank− 732 of the VCO core 728. The gate of Ml 734 may be connected to an output Vtank+ 740 of the VCO core 728. The VCO core 728 may include a second NMOS transistor M2 738, with the source of M2 738 connected to ground and the drain of M2 738 connected to the output Vtank+ 740. The gate of M2 738 may be connected to the output Vtank− 732.

The VCO core 728 may also include a first p-type metal-oxide-semiconductor (PMOS) field effect transistor M3 730 with the source of M3 730 connected to the positive rail Vdd and the drain of M3 730 connected to the output Vtank− 732 of the VCO core 728. The gate of M3 730 may be connected to the output Vtank+ 740. The VCO core 728 may further include a second PMOS transistor M4 742, with the source of M4 742 connected to Vdd, the drain of M4 742 connected to the output Vtank+ 740 and the gate of M4 742 connected to the output Vtank− 732. An inductor/capacitor (LC) tank 736 may connect Vtank+ 740 and Vtank− 732. The inductor/capacitor (LC) tank 736 may include an inductor and a bank of switched capacitors coupled in a resonant circuit designed to generate an oscillating signal. For example, the LC tank 736 may include a capacitor bank 540 as illustrated in FIG. 5.

The outputs of the VCO core 728 may be input into a VCO buffer 726. The VCO buffer 726 of FIG. 7 may be one configuration of the VCO buffer 626 illustrated in FIG. 6. The VCO buffer 726 may include a VCO buffer first portion 719a that receives Vtank+ 740 from the VCO core 728 and a VCO buffer second portion 719b that receives Vtank− 732 from the VCO core 728.

The VCO buffer first portion 719a receiving Vtank+ 740 may include a first capacitor 754 and a second capacitor 758; each capacitor is connected to Vtank+ 740. In one configuration, the first capacitor 754 and/or the second capacitor 758 may be implemented with the switched capacitor 412 illustrated in FIG. 4 or a capacitance produced from the capacitor bank 540 illustrated in FIG. 5. The node on the other side of the first capacitor 754 may include a resistor 723c connecting the node to the direct current (DC) bias voltage Vp 725b of a PMOS transistor M5 761. The node may also be connected to the gate of the PMOS transistor M5 761. Similarly, the node on the other side of the second capacitor 758 may include a resistor 723d connecting the node to the DC bias voltage Vn 727b of an NMOS transistor M6 762. The node may also be connected to the gate of the NMOS transistor M6 762. The source of M6 762 may be connected to ground and the drain of M6 762 may be connected to an output Vlo− 760 of the VCO buffer 726. The source of M5 761 may be connected to Vdd and the drain of M5 761 may be connected to the output Vlo− 760.

The VCO buffer second portion 719b receiving Vtank− 732 may include a third capacitor 744 and a fourth capacitor 748, where each capacitor is connected to Vtank− 732. In one configuration, the third capacitor 744 and/or the fourth capacitor 748 may be implemented with the switched capacitor 412 illustrated in FIG. 4 or a capacitance produced from the capacitor bank 540 illustrated in FIG. 5. The node on the other side of the third capacitor 744 may include a resistor 723a connecting the node to Vp 725a. The node may connect the third capacitor 744 to the gate of a PMOS transistor M7 746. Similarly, the node on the other side of the fourth capacitor 748 may include a resistor 723b connecting the node to Vn 727a. The node may also connect the fourth capacitor 748 to the gate of an NMOS transistor M8 752. The source of M8 752 may be connected to ground and the drain of M8 752 may be connected to an output Vlo+ 750 of the VCO buffer 726. The source of M7 746 may be connected to Vdd and the drain of M7 746 may be connected to the output Vlo+ 750. Vtank+ 740 and Vtank− 732 may have a 3 volt (V) differential peak waveform for meeting stringent phase noise specifications.

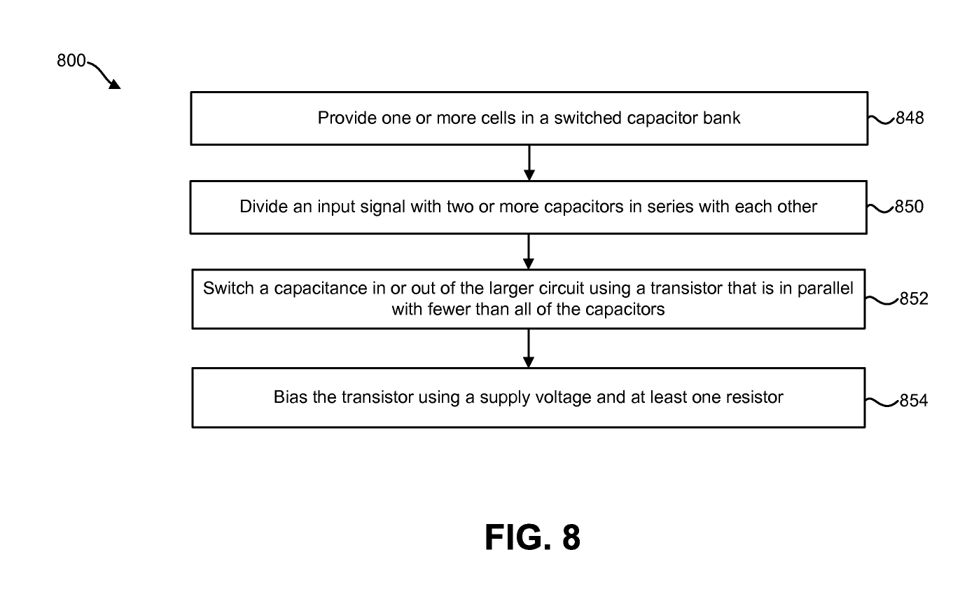

FIG. 8 is a flow diagram illustrating a method 800 for including or excluding a capacitance from a larger circuit. The method 800 may be performed by a base station 102 or a wireless communication device 104. The wireless communication device 104 may provide 848 one or more cells in a switched capacitor bank 540. The cells may be binary bit incremented or identical. Each cell may divide 850 an input signal with two or more capacitors in series with each other. The capacitors may divide the input signal, according to Equation (1), so that the voltage swing across a transistor is less than if the input voltage was not divided. Each cell may also switch 852 a capacitance in or out of a larger circuit using the transistor that is in parallel with fewer than all of the capacitors, i.e., the transistor may operate to include or exclude a capacitance from a larger circuit. The larger circuit may be a VCO or a power amplifier. Each cell may also bias 854 the transistor using a supply voltage and at least one resistor.

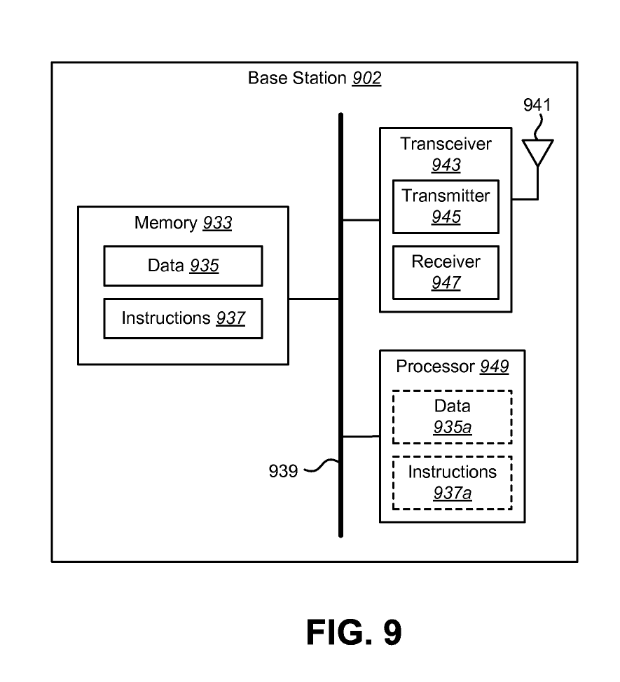

FIG. 9 illustrates certain components that may be included within base station 902. The base station 102 or communication devices discussed previously may be configured similarly to the base station 902 shown in FIG. 9. It should also be noted that a base station 902 may be a communication device as termed herein.

The base station 902 includes a processor 949. The processor 949 may be a general purpose single- or multi-chip microprocessor (e.g., an ARM), a special purpose microprocessor (e.g., a digital signal processor (DSP)), a microcontroller, a programmable gate array, etc. The processor 949 may be referred to as a central processing unit (CPU). Although just a single processor 949 is shown in the base station 902 of FIG. 9, in an alternative configuration, a combination of processors (e.g., an ARM and DSP) could be used.

The base station 902 also includes memory 933 in electronic communication with the processor 949 (i.e., the processor 949 can read information from and/or write information to the memory 933). The memory 933 may be any electronic component capable of storing electronic information. The memory 933 may be random access memory (RAM), read-only memory (ROM), magnetic disk storage media, optical storage media, flash memory devices in RAM, on-board memory included with the processor, programmable read-only memory (PROM), erasable programmable read-only memory (EPROM), electrically erasable PROM (EEPROM), registers, and so forth, including combinations thereof

Data 935 and instructions 937 may be stored in the memory 933. The instructions 937 may include one or more programs, routines, sub-routines, functions, procedures, etc. The instructions 937 may include a single computer-readable statement or many computer-readable statements. The instructions 937 may be executable by the processor 949 to implement the methods disclosed in connection with the access point 102, base station or communication device. Executing the instructions 937 may involve the use of the data 935 that is stored in the memory 933. FIG. 9 shows some instructions 937a and data 935a being loaded into the processor 949.

The base station 902 may also include a transmitter 945 and a receiver 947 to allow transmission and reception of signals between the base station 902 and a remote location. The transmitter 945 and receiver 947 may be collectively referred to as a transceiver 943. An antenna 941 may be electrically coupled to the transceiver 943. The base station 902 may also include (not shown) multiple transmitters, multiple receivers, multiple transceivers and/or multiple antenna.

The various components of the base station 902 may be coupled together by one or more buses, which may include a power bus, a control signal bus, a status signal bus, a data bus, etc. For simplicity, the various buses are illustrated in FIG. 9 as a bus system 939.

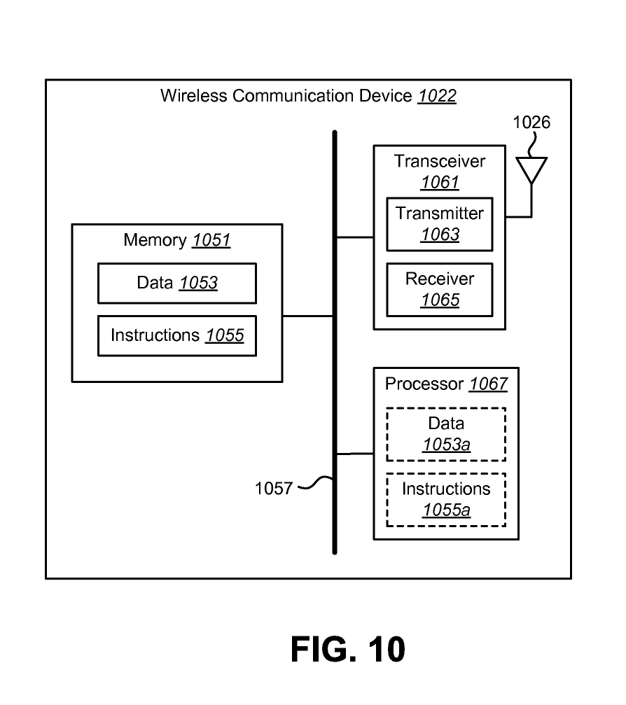

FIG. 10 illustrates certain components that may be included within a wireless communication device 1022. The wireless communication device 104 in FIG. 1 may be configured similarly to the wireless communication device 1022 that is shown in FIG. 10. Examples of wireless communication devices 1022 include cellular phones, handheld wireless devices, wireless modems, laptop computers, personal computers, etc.

The wireless communication device 1022 includes a processor 1067. The processor 1067 may be a general purpose single- or multi-chip microprocessor (e.g., an ARM), a special purpose microprocessor (e.g., a digital signal processor (DSP)), a microcontroller, a programmable gate array, etc. The processor 1067 may be referred to as a central processing unit (CPU). Although just a single processor 1067 is shown in the wireless communication device 1022 of FIG. 10, in an alternative configuration, a combination of processors (e.g., an ARM and DSP) could be used.

The wireless communication device 1022 also includes memory 1051 in electronic communication with the processor 1067 (i.e., the processor 1067 can read information from and/or write information to the memory 1051). The memory 1051 may be any electronic component capable of storing electronic information. The memory 1051 may be random access memory (RAM), read-only memory (ROM), magnetic disk storage media, optical storage media, flash memory devices in RAM, on-board memory included with the processor, programmable read-only memory (PROM), erasable programmable read-only memory (EPROM), electrically erasable PROM (EEPROM), registers, and so forth, including combinations thereof

Data 1053 and instructions 1055 may be stored in the memory 1051. The instructions 1055 may include one or more programs, routines, sub-routines, functions, procedures, etc. The instructions 1055 may include a single computer-readable statement or many computer-readable statements. The instructions 1055 may be executable by the processor 1067 to implement the methods that were described above in connection with the access terminals 122. Executing the instructions 1055 may involve the use of the data 1053 that is stored in the memory 1051. FIG. 10 shows some instructions 1055a and data 1053a being loaded into the processor 1067.

The wireless communication device 1022 may also include a transmitter 1063 and a receiver 1065 to allow transmission and reception of signals between the wireless communication device 1022 and a remote location. The transmitter 1063 and receiver 1065 may be collectively referred to as a transceiver 1061. An antenna 1026 may be electrically coupled to the transceiver 1061. The wireless communication device 1022 may also include (not shown) multiple transmitters, multiple receivers, multiple transceivers and/or multiple antenna.

The various components of the wireless communication device 1022 may be coupled together by one or more buses, which may include a power bus, a control signal bus, a status signal bus, a data bus, etc. For simplicity, the various buses are illustrated in FIG. 10 as a bus system 1057.

The term “determining” encompasses a wide variety of actions and, therefore, “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

The phrase “based on” does not mean “based only on,” unless expressly specified otherwise. In other words, the phrase “based on” describes both “based only on” and “based at least on.”

The term “processor” should be interpreted broadly to encompass a general purpose processor, a central processing unit (CPU), a microprocessor, a digital signal processor (DSP), a controller, a microcontroller, a state machine, and so forth. Under some circumstances, a “processor” may refer to an application specific integrated circuit (ASIC), a programmable logic device (PLD), a field programmable gate array (FPGA), etc. The term “processor” may refer to a combination of processing devices, e.g., a combination of a DSP and a microprocessor, a plurality of microprocessors, one or more microprocessors in conjunction with a DSP core, or any other such configuration.

The term “memory” should be interpreted broadly to encompass any electronic component capable of storing electronic information. The term memory may refer to various types of processor-readable media such as random access memory (RAM), read-only memory (ROM), non-volatile random access memory (NVRAM), programmable read-only memory (PROM), erasable programmable read-only memory (EPROM), electrically erasable PROM (EEPROM), flash memory, magnetic or optical data storage, registers, etc. Memory is said to be in electronic communication with a processor if the processor can read information from and/or write information to the memory. Memory that is integral to a processor is in electronic communication with the processor.

The terms “instructions” and “code” should be interpreted broadly to include any type of computer-readable statement(s). For example, the terms “instructions” and “code” may refer to one or more programs, routines, sub-routines, functions, procedures, etc. “Instructions” and “code” may comprise a single computer-readable statement or many computer-readable statements.

The functions described herein may be implemented in hardware, software, firmware, or any combination thereof. If implemented in software, the functions may be stored as one or more instructions on a computer-readable medium. The terms “computer-readable medium” or “computer-program product” refers to any available medium that can be accessed by a computer. By way of example, and not limitation, a computer-readable medium may comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Disk and disc, as used herein, includes compact disc (CD), laser disc, optical disc, digital versatile disc (DVD), floppy disk and Blu-ray® disc where disks usually reproduce data magnetically, while discs reproduce data optically with lasers.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

Further, it should be appreciated that modules and/or other appropriate means for performing the methods and techniques described herein, such as those illustrated by FIG. 8 can be downloaded and/or otherwise obtained by a device. For example, a device may be coupled to a server to facilitate the transfer of means for performing the methods described herein. Alternatively, various methods described herein can be provided via a storage means (e.g., random access memory (RAM), read only memory (ROM), a physical storage medium such as a compact disc (CD) or floppy disk, etc.), such that a device may obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. An integrated circuit comprising a capacitor bank, the bank comprising:
one or more cells, wherein each cell comprises:
two capacitors in series; and
a transistor in parallel with one of the capacitors.

2. The integrated circuit of claim 1, wherein each cell further comprises one or more resistors that bias the transistor using a control signal.

3. The integrated circuit of claim 1, wherein the transistor is an n-type metal-oxide-semiconductor (NMOS) field effect transistor.

4. The integrated circuit of claim 1, wherein capacitances of the capacitors are matched in a 1:1 ratio.

5. The integrated circuit of claim 1, wherein capacitances of the capacitors are not matched in a 1:1 ratio.

6. The integrated circuit of claim 1, wherein a largest capacitance of a second cell is double a largest capacitance of a first cell and half a largest capacitance of a third cell.

7. The integrated circuit of claim 1, wherein the transistor switches a capacitance of the parallel capacitor in or out of a larger circuit.

8. The integrated circuit of claim 7, wherein the larger circuit comprises a voltage controlled oscillator (VCO) core, comprising:
an inductor/capacitor (LC) tank that generates a desired frequency using the capacitor bank; and
a first n-type metal-oxide-semiconductor (NMOS) field effect transistor with a source connected to ground, a drain connected to a first VCO core output and a gate connected to a second VCO core output;
a second NMOS field effect transistor with a source connected to ground, a drain connected to the second VCO core output and a gate connected to the first VCO core output;
a first p-type metal-oxide-semiconductor (PMOS) field effect transistor with a source connected to a voltage supply, a drain connected to the first VCO core output and a gate connected to the second VCO core output; and
a second PMOS field effect transistor with a source connected to the voltage supply, a drain connected to the second VCO core output and a gate connected to the first VCO core output.

9. The integrated circuit of claim 8, wherein the larger circuit further comprises a buffer, comprising:
a first portion, comprising:
a first capacitance connected to the second VCO core output and a gate of a third p-type metal-oxide-semiconductor (PMOS) field effect transistor;
the third PMOS field effect transistor with a source connected to the voltage supply and a drain connected to the first portion output;
a second capacitance connected to the second VCO core output and a gate of a third n-type metal-oxide-semiconductor (NMOS) field effect transistor;
the third NMOS field effect transistor with a source connected to ground and a drain connected to the first portion output; and
a second portion, comprising:
a third capacitance connected to the first VCO core output and a gate of a fourth p-type metal-oxide-semiconductor (PMOS) field effect transistor;
the fourth PMOS field effect transistor with a source connected to the voltage supply and a drain connected to the second portion output;
a fourth capacitance connected to the first VCO core output and a gate of a fourth n-type metal-oxide-semiconductor (NMOS) field effect transistor; and
the fourth NMOS field effect transistor with a source connected to ground and a drain connected to the second portion output.

10. The integrated circuit of claim 9, wherein one or more of the first capacitance, second capacitance, third capacitance and fourth capacitance are generated using the capacitor bank.

11. An apparatus comprising a capacitor bank, the bank comprising:
one or more cells, wherein each cell comprises:
two capacitors in series; and
a transistor in parallel with one of the capacitors.

12. The apparatus of claim 11, wherein each cell further comprises one or more resistors that bias the transistor using a control signal.

13. The apparatus of claim 11, wherein the transistor is an n-type metal-oxide-semiconductor (NMOS) field effect transistor.

14. The apparatus of claim 11, wherein capacitances of the capacitors are matched in a 1:1 ratio.

15. The apparatus of claim 11, wherein capacitances of the capacitors are not matched in a 1:1 ratio.

16. The apparatus of claim 11, wherein a largest capacitance of a second cell is double a largest capacitance of a first cell and half a largest capacitance of a third cell.

17. The apparatus of claim 11, wherein the transistor switches a capacitance of the parallel capacitor in or out of a larger circuit.

18. The apparatus of claim 17, wherein the larger circuit comprises a voltage controlled oscillator (VCO) core, comprising:
an inductor/capacitor (LC) tank that generates a desired frequency using the capacitor bank; and
a first n-type metal-oxide-semiconductor (NMOS) field effect transistor with a source connected to ground, a drain connected to a first VCO core output and a gate connected to a second VCO core output;
a second NMOS field effect transistor with a source connected to ground, a drain connected to the second VCO core output and a gate connected to the first VCO core output;
a first p-type metal-oxide-semiconductor (PMOS) field effect transistor with a source connected to a voltage supply, a drain connected to the first VCO core output and a gate connected to the second VCO core output; and
a second PMOS field effect transistor with a source connected to the voltage supply, a drain connected to the second VCO core output and a gate connected to the first VCO core output.

19. The apparatus of claim 18, wherein the larger circuit further comprises a buffer, comprising:
a first portion, comprising:
a first capacitance connected to the second VCO core output and a gate of a third p-type metal-oxide-semiconductor (PMOS) field effect transistor;
the third PMOS field effect transistor with a source connected to the voltage supply and a drain connected to the first portion output;
a second capacitance connected to the second VCO core output and a gate of a third n-type metal-oxide-semiconductor (NMOS) field effect transistor;
the third NMOS field effect transistor with a source connected to ground and a drain connected to the first portion output; and
a second portion, comprising:
a third capacitance connected to the first VCO core output and a gate of a fourth p-type metal-oxide-semiconductor (PMOS) field effect transistor;
the fourth PMOS field effect transistor with a source connected to the voltage supply and a drain connected to the second portion output;
a fourth capacitance connected to the first VCO core output and a gate of a fourth n-type metal-oxide-semiconductor (NMOS) field effect transistor; and
the fourth NMOS field effect transistor with a source connected to ground and a drain connected to the second portion output.

20. The apparatus of claim 19, wherein one or more of the first capacitance, second capacitance, third capacitance and fourth capacitance are generated using the capacitor bank.

21. An apparatus comprising a capacitor bank, the bank comprising:
one or more cells, wherein each cell comprises:
two capacitive means in series; and
a means for switching in parallel with one of the capacitive means.

22. The apparatus of claim 21, wherein each cell further comprises one or more resistive means that bias the means for switching using a control signal.

23. The apparatus of claim 21, wherein the means for switching is an n-type metal-oxide-semiconductor (NMOS) field effect transistor.

24. The apparatus of claim 21, wherein capacitances of the capacitive means are matched in a 1:1 ratio.

25. The apparatus of claim 21, wherein capacitances of the capacitive means are not matched in a 1:1 ratio.

26. The apparatus of claim 21, wherein a largest capacitance of a second cell is double a largest capacitance of a first cell and half a largest capacitance of a third cell.

27. The apparatus of claim 21, wherein the means for switching switches a capacitance of the parallel capacitive means in or out of a larger circuit.

28. A method for including or excluding a capacitance from a larger circuit, the method comprising:
dividing an input signal with two or more capacitors in series with each other; and
switching a capacitance in or out of the larger circuit using a transistor that is in parallel with fewer than all of the capacitors.

29. The method of claim 28, further comprising biasing the transistor using a control signal and at least one resistor.

30. The method of claim 28, wherein the transistor is an n-type metal-oxide-semiconductor (NMOS) field effect transistor.

31. The method of claim 28, wherein capacitances of the capacitors are matched in a 1:1 ratio.

32. The method of claim 28, wherein capacitances of the capacitors are not matched in a 1:1 ratio.

33. The method of claim 28, wherein a largest capacitance of a second cell is double a largest capacitance of a first cell and half a largest capacitance of a third cell.
